(19) United States
(12) Patent Application Publication
(10) Pub. No.: US 2009/0102036 A1
(43) Pub. Date: Apr. 23, 2009

(54) Stacked semiconductor package having interposing print circuit board

(76) Inventor: Sung-Wook Hwang, Seongnam-si (KR)

Correspondence Address: HARNESS, DICKEY & PIERCE, P.L.C., P.O. BOX 8910, RESTON, VA, 20195, US

(21) Appl. No.: 12/232,149

(22) Filed: Sep. 11, 2008

Related U.S. Application Data
(62) Division of application No. 11/332,185, filed on Jan. 17, 2006, now abandoned.

(30) Foreign Application Priority Data
Jan. 17, 2005 (KR) 10-2005-0004140

(51) Int. Cl. H01L 23/14

(52) U.S. Cl. 257/686; 257/E23.005

(57) ABSTRACT

A stacked semiconductor package including a number of solder ball pads formed on a lower surface of an interposing print circuit board, which is smaller than that of solder ball pads formed on an upper surface thereof, a pitch of the solder ball pads formed on the lower surface of the interposing print circuit board is greater than a pitch of the solder ball pads formed on the upper interposing print circuit board.

### PRIORITY CLAIM

This is a divisional of, and claims priority under 35 U.S.C. §120 to, U.S. application Ser. No. 11/332,185, filed Jan. 17, 2006, which claims priority under U.S.C. §119 to Korean Patent Application No. 10-2005-0004140, filed Jan. 17, 2005, in the Korean Intellectual Property Office, the entire contents of which are herein incorporated reference.

### BACKGROUND OF THE INVENTION

1. Field of the Invention

Example embodiments of the present invention generally relate to a semiconductor device. More particularly, example embodiments of the present invention relate to a stacked type semiconductor package having an interposing printed circuit board.

2. Description of the Related Art

The degree of integration in a wafer level has advanced to increase the capacity and function of a semiconductor package. A semiconductor package may include the integration of two or more semiconductor chips or two or more semiconductor packages. To increase functions and capacities of a wafer-level semiconductor device require equipment investment, which means additional manufacturing costs. It also means that problems associated with integrating new equipment must also be solved.

However, techniques of integrating two or more semiconductor chips or two or more semiconductor packages to increase functions and capacities of a semiconductor package do not have the same problems as the wafer-level semiconductor device. The integration can be accomplished with only a small equipment investment at low cost. Integrated semiconductor packages include a system in package (SIP), a multi-chip package (MCP), and a package-on-package (POP).

POPs is a type of package that integrates two or more complete semiconductor packages. POPs has an advantage because only complete packages are used, defective packages can be selectively removed prior to integration.

FIG. 1 is a cross-sectional view illustrating a ball grid array (BGA) stacked semiconductor package of the prior art. Referring to FIG. 1, a first semiconductor package 20 having solder balls 28 as external connectors and a second semiconductor package 10 are vertically stacked to produce a stacked semiconductor package. A first substrate 22 of the first semiconductor package 20 includes first solder balls pads 26 on a first surface side of the first substrate 22 also having the solder balls 28 attached thereto. Second solder pads 24 are formed on a second surface side of the first substrate 22.

The second semiconductor package 10 includes a second substrate 12. The second substrate 12 includes third solder balls pads 14 on a first surface side of the second substrate 12, and is attached to a main body 18 on its second surface side thereof. Accordingly, solder balls 16 connect the first semiconductor package 20 with the second semiconductor package 10 at the second solder ball pads 24 and the third solder ball pads 14. Reference numeral 30 denotes a package main body of the first semiconductor package 20.

To manufacture the stacked semiconductor packages of FIG. 1, a height of the solder balls 16 should be greater than a height of the package main body 30. However, as the number of pins in the second semiconductor package 10 has increased, the size of the solder balls 16 has decreased to allow the solder balls 16 to be arranged within a limited area. This arrangement also decreases a pitch between adjacent solder balls 16. Hence, if the height of the solder balls 16 is smaller than the height of the main body 30, the first and second semiconductor packages 20 and 10 cannot be stacked.

FIG. 2 is a cross-sectional view illustrating another prior art stacked semiconductor package. This prior art stacked semiconductor package is a vertically stacked semiconductor package. This type of vertically stacked semiconductor package may solve the problem described above with reference to FIG. 1 by interposing a connector 40 between a second semiconductor package 50 and a first semiconductor package 60. The connector 40 includes an interposing printed circuit board (PCB) 42 and solder balls 44 attached to the interposing printed circuit board 42.

The connector 40 only connects the second semiconductor package 50 to the first semiconductor package 60 in a one-to-one manner with the solder balls. However, problems will occur if the pitch changes due to an increase in the number of solder balls on the second semiconductor package 50.

### SUMMARY OF THE INVENTION

In an embodiment of the present invention, a stacked semiconductor package includes a first semiconductor device, a second semiconductor device, and a connector to connect to the first device with the second device. The connector includes a substrate having a first side and a second side, first solder ball pads formed on the first side of the substrate, second solder ball pads formed on the second side of the substrate, wherein a pitch between the first solder ball pads is greater than a pitch between the second solder land pads and pitch is the distance between directly adjacent solder ball pads.

In another embodiment of the present invention, a stacked semiconductor package includes a first semiconductor device, a second semiconductor device, and a connector to connect to the first device with the second device. The connector includes a substrate having a first side and a second side, first solder ball pads formed on the first side of the substrate, second solder ball pads formed on the second side of the substrate, wherein a number of the second solder ball pads is greater than a number of the first solder ball pads.

In another embodiment of the present invention, a stacked semiconductor package includes a first semiconductor device, a second semiconductor device, and a connector to connect to the first device with the second device. The connector includes a substrate having a first side and a second side, first solder ball pads formed on the first side of the substrate, second solder ball pads formed on the second side of the substrate, wherein a number of the second solder ball pads is greater than a number of the first solder ball pads, and a pitch between the first solder ball pads is greater than a pitch between the second solder ball pads.

### BRIEF DESCRIPTION OF THE DRAWINGS

The present invention will become more apparent with the description of the detail example embodiments thereof with reference to the attached drawings in which:

FIG. 1 is a cross-sectional view illustrating a stacked ball grid array (BGA) semiconductor package of the prior art;

FIG. 2 is a cross-sectional view illustrating another prior art stacked semiconductor package;

FIG. 3 is a cross-sectional view illustrating a stacked semiconductor package having an interposing printed circuit board according to an embodiment of the present invention;

FIG. 4 is an example cross-sectional view illustrating a main body of a first package shown in FIG. 3;

FIG. 5 is an example exploded perspective view of the stacked semiconductor package of FIG. 3;

FIG. 6 is an example plan illustrating a second surface of a package connector shown in FIG. 4; and

FIG. 7 is an example plan illustrating a first surface of the package connector shown in FIG. 4.

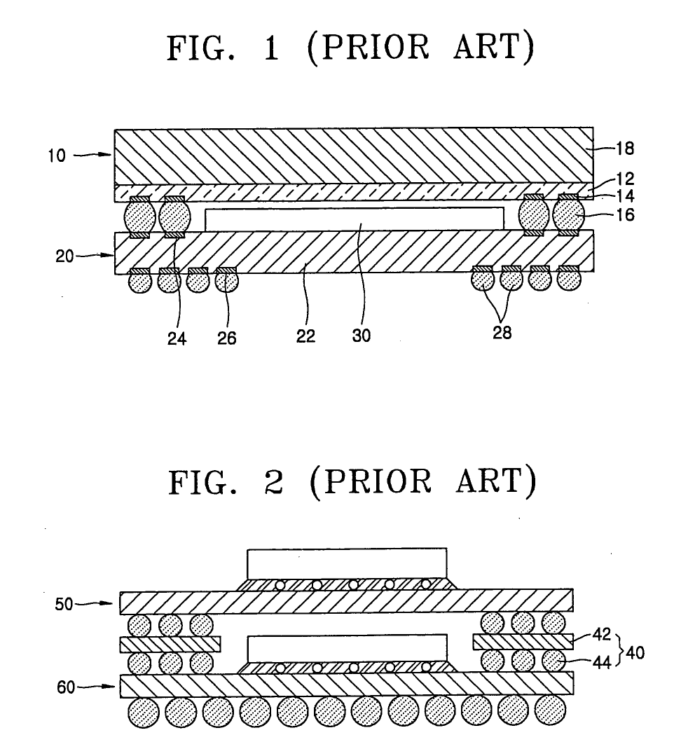

### DETAILED DESCRIPTION OF EXAMPLE EMBODIMENTS OF THE INVENTION

The present invention will now be described more fully with reference to the accompanying drawings, in which example embodiments of the present invention are shown. However, the present invention should not be construed as being limited to the example embodiments set forth herein; rather, these example embodiments are provided as working examples.

Throughout the specification, designation numerals, for example, “first,” “second,” and “third” are used. The designation numerals are not used to limit or specify a specific element or method; but rather, the designation numerals are used to distinguish one element from another element for explanation purposes.

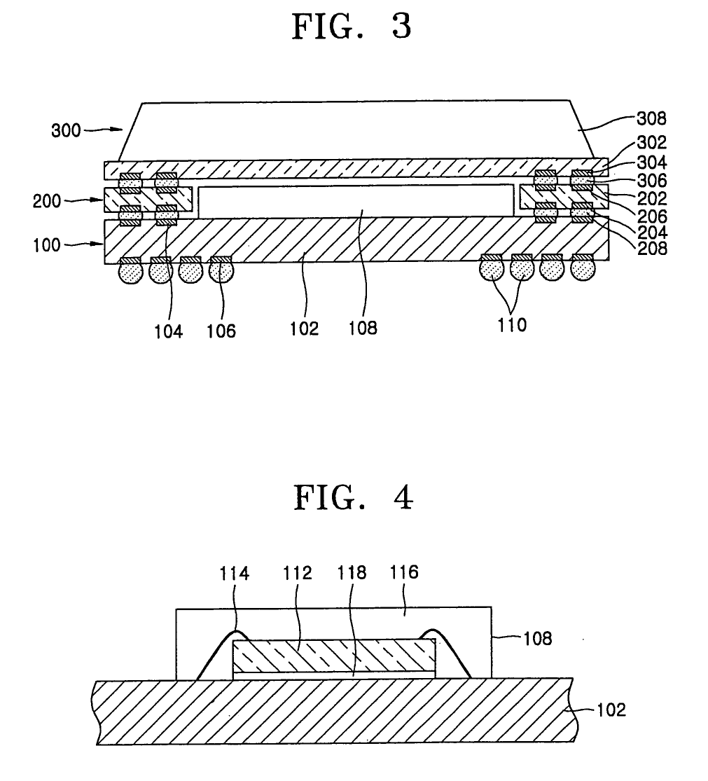

FIG. 3 is a cross-sectional view illustrating a stacked semiconductor package having an interposing printed circuit board according to an embodiment of the present invention. Referring to FIG. 3, a stacked semiconductor package may include a first semiconductor package 100, a package connector 200, and a second semiconductor package 300.

The first semiconductor package 100 may include a first substrate 102, which may be a multi-layered substrate and has a first surface side and a second surface side. The first substrate 102 may include first solder ball pads 106 having first solder balls 110 attached thereto formed on the first surface side, and second solder ball pads 104 and a first package main body 108 formed on the second surface side.

The second solder ball pads 104 may be used to receive external signals. The first package main body 108 may be formed by mounting and connecting a semiconductor chip (not shown) on the first substrate 102, and sealing the semiconductor chip with epoxy mold compound. Additional details will be given with reference to FIG. 4.

The package connector 200 may include an interposing printed circuit board (PCB) 202, which may be a multi-layered substrate having an opening at the center. The interposing PCB 202 may include third solder ball pads 204 formed on a first surface side and fourth solder ball pads 206 formed a second surface side. First connecting terminals 208 connect the third solder ball pads 204 with the second solder ball pads 104. The first connecting terminals 208 may be either solder balls or solder lands.

An aspect of an embodiment of the present invention may be achieved by changing structures of the interposing PCB 202 and the third and fourth solder ball pads 204 and 206. For example, in a method of changing the structures of the interposing PCB 202 and the third and fourth solder ball pads 204 and 206, when the fourth solder ball pads 206 formed on the second surface of the interposing print circuit board 202, they should be connected to the third solder ball pads 204, but pins used only during an electrical test and No-Connection (NC) pins among the third solder ball pads 204 are not connected to the fourth solder ball pads 206.

The NC pins may be formed in accordance with the international standard set by the Joint Electron Device Engineering Council, but are not actually used. For example, a 512M SDRAM manufactured by Samsung includes about 7-10 NC pins. The NC pins may be only used during a final electrical test by the manufacturer. The NC pins need not be used by an end user. In another example, a flash memory having word/byte selection pins, hardware write protection pins, and program acceleration pins correspond to the pins used only during an electrical test, only about 3-6 pins are used during an electrical test.

In another example method of changing the structures of the interposing print circuit board 202 and the third and fourth solder ball pads 204 and 206, if the third solder ball pads 204 are connected to the fourth solder ball pads 206, the number of power supply signal lines, for example, Vdd pins or ground pins, included in the third solder ball pads 204 may increase. Thereby, the characteristic of the power supply signal lines, namely, electrical signal transmission between the upper and lower semiconductor packages 300 and 100 may be improved.

According, the number of third solder ball pads 204 decreases while being connected to the fourth solder ball pads 206 via the interposing print circuit board 202. Consequently, the third solder ball pads 204 may be arranged to have a greater pitch than the fourth solder ball pads 206.

The second semiconductor package 300 may include a second substrate 302. The second substrate 302 may include first and second surface sides. Fifth solder ball pads 304 may be formed on the first surface of the second substrate 302, and second connecting terminals 306 may connect the fifth solder ball pads 304 with the fourth solder ball pads 206. A second package main body 308 may be formed on the second substrate 302. The second connecting terminals 306 may be either a solder ball or a solder land. The connection of the second connecting terminals 306 to the fourth solder ball pads 206 is in a one-to-one corresponding manner. Similar to the first package main body 108, the second package main body 308 may have a semiconductor chip mounted and connected (not shown) to the second substrate 302, and sealed with epoxy mold compound. The semiconductor chip may be connected to the second substrate 302 by a wire bonding technique or a flip chip bonding technique.

FIG. 4 is an example cross-sectional view illustrating the first package main body 108 of FIG. 3. Referring to FIG. 4, the first package main body 108 may include a semiconductor chip 112, which may be mounted on an adhesive tape 118 formed on second surface side of the first substrate 102. A wire 114 may be used to electrically connect a bonding pad (not shown) of the semiconductor chip 112 to the first substrate 102. An epoxy mold compound 116 may seal the semiconductor 112, the adhesive tape 118, and the wire 114. Instead of the wire bonding technique to electrically connect the semiconductor chip 112 to the first substrate 102, a flip chip bonding technique may be used.

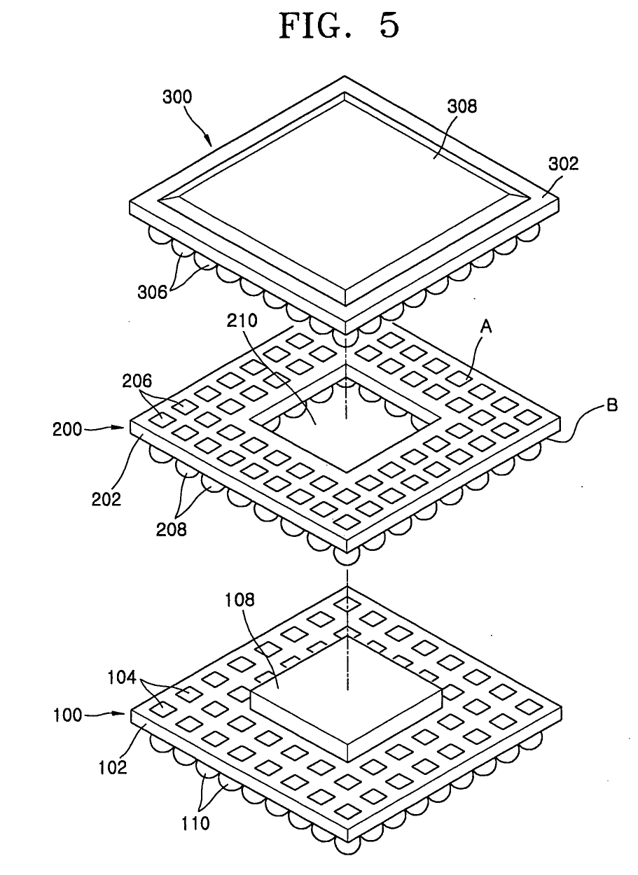

FIG. 5 is an example exploded perspective view illustrating the stacked semiconductor package of FIG. 3. Referring to FIG. 5, the first semiconductor package 100 may be connected to the package connector 200 via the first connecting terminals 208. The first package main body 108 may be adapted to be inserted into an opening 210 formed at the center of the package connector 200. The package connector 200 and the second semiconductor package 300 may be adapted to be coupled together by connecting the second connecting terminals 306 to the fourth solder ball pads 206 in an one-to-one manner.

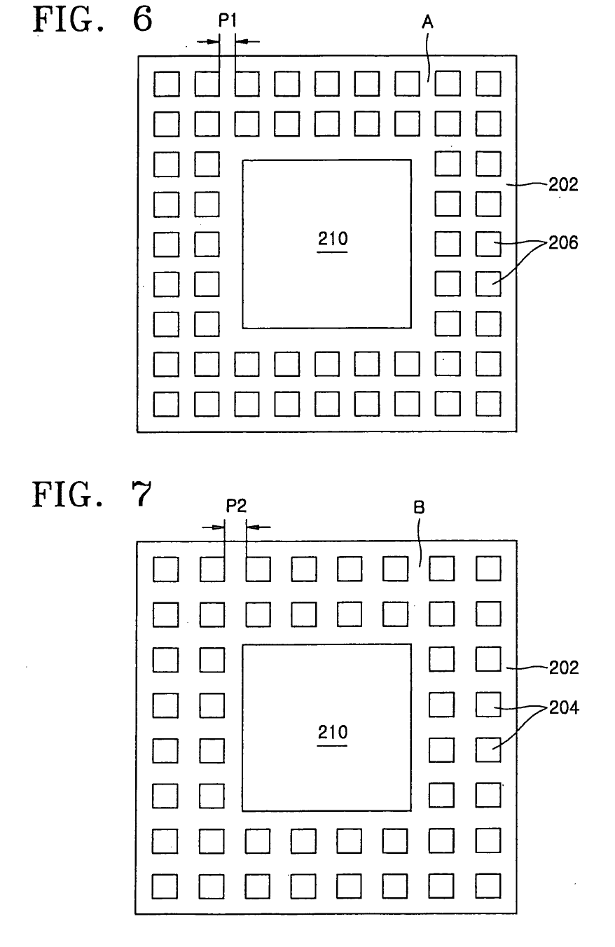

Even if the number of pins formed on the second semiconductor package 300 increases, the number of pads that connect the pins to the first semiconductor package 100 may be reduced, and a pitch between the pads may be increased. This effect will now be described in greater detail with reference to FIGS. 6 and 7.

FIG. 6 is an example plan view of the second surface A of the package connector 200. FIG. 7 is a plan view of the first surface B of the package connector 200.

Referring to FIGS. 6 and 7, the opening 210 at the center of the package connector 200 may be wider than the width of the first package main body 108. As illustrated in FIG. 6, the fourth solder ball pads 206 may have a pitch, P1.

The pitch P1 between fourth solder ball pads 206 may be reduced to 5 μm or less with higher integration. A pitch P2 between third solder ball pads 204 may be increased to 6.5 μm or more if the first semiconductor package 100 is a large-scale integrated (LSI) device, such as a microcontroller or microprocessor.

To solve this type of problem, in example embodiments of the present invention, if the number of fourth solder ball pads 206 on the second surface of the package connector is 56, the number of third solder ball pads 204 connected to the fourth solder ball pads 206 may be reduced to 48 as shown in FIG. 7. This reduction in the third solder ball pads 204 results from not connecting NC pins and other pins not used by an end user. The pitch P2 between third solder ball pads 204 may increase on the first surface according to the number of pads (56−48=8) by reducing the number of third solder balls pads 204.

In other embodiments of the present invention, the number of power supply signal lines, for example, Vdd pins or ground pins, of the third solder ball pads 206 may be increased to thereby improve signal transmission between the first and second semiconductor packages 100 and 300.

While example embodiments of the present invention has been described, it will be understood by those of ordinary skill in the art that various changes in form and details may be made therein without departing from the scope of the example embodiments of the present invention.

1-12. (canceled)

13. A stacked semiconductor package, comprising:
a first semiconductor device;
a second semiconductor device;
a connector to connect to the first device with the second device, including:
a substrate having a first side and a second side;
first solder ball pads formed on the first side of the substrate;
second solder ball pads formed on the second side of the substrate;
wherein a number of the second solder ball pads is greater than a number of the first solder ball pads, and a pitch between the first solder ball pads is greater than a pitch between the second solder ball pads.

14. The package of claim 13, wherein the first semiconductor includes third solder ball pads connected to the first solder ball pads via a first connecting terminal, and wherein the second semiconductor includes fourth solder ball pads connected to the second solder ball pads via a second connecting terminal.

15. The package of claim 13, wherein all the first solder ball pads are connected to the second solder ball pads, but not all the second solder ball pads are connected to the first solder ball pads.

16. The package of claim 15, wherein the second solder ball pads not connected to the first solder ball pads are used as no-connection (NC) pins.

17. The package of claim 13, wherein the first and second semiconductor devices are one of a memory device, a semiconductor memory package, or a large-scale integrated (LSI) device.

18. The package of claim 17, wherein the LSI device is one of microcontroller or a microprocessor.
